(19) United States
(12) Patent Application Publication
(10) Pub. No.: US 2024/0076773 A1
(43) Pub. Date: Mar. 7, 2024

(54) METAL MATERIAL AND METHOD FOR PRODUCING THE SAME

(71) Applicant: City University of Hong Kong Shenzhen Futian Research Institute, Guangdong (CN)

(72) Inventors: Sida Liu, Guangdong (CN); Jian Lu, Guangdong (CN)

(21) Appl. No.: 17/992,638

(22) Filed: Nov. 22, 2022

(30) Foreign Application Priority Data
Sep. 5, 2022 (CN) 202211077399.4

(51) Int. Cl. C23C 14/35; C23C 14/14; C23C 14/34; C23C 14/54

(52) U.S. Cl. CPC C23C 14/35; C23C 14/14; C23C 14/3407; C23C 14/541

(57) ABSTRACT

Provided is a metal material including a plurality of metal particles arranged in a crystal structure having at least two phases; wherein the at least two phases include a crystalline phase and an amorphous phase.

### PRIORITY

The present application claims priority to Chinese patent application No. 202211077399.4, filed on 5 Sep. 2022, with the title “Metal Material and Method for producing the Same”, which is hereby incorporated by reference in its entirety.

### TECHNICAL FIELD

The present disclosure relates to a metal material and a method for producing the same, and particularly, although not exclusively, to a metal material comprising a plurality of metal particles arranged in a crystal structure having at least two phases, which has excellent mechanical properties such as strength and toughness and may be used as a catalyst such as electrocatalyst, and a method for producing the same.

### BACKGROUND

Renewable clean energy technology is developing rapidly in the past few decades, and abundant clean fuels, such as hydrogen (H₂), are expected to replace fossil fuels in the future. Electrocatalytic water splitting is a reliable, eco-friendly, and widely-used technique to produce hydrogen in the industry. Pt-based catalysts are used in hydrogen evolution reaction (HER) towards water electrolysis, which are regarded as a class of the most efficient catalysts in both acid and alkaline electrolytes, yet the concern of their price is still an issue. Therefore, the demand to develop low-cost and reliable electrocatalysts is desired.

### SUMMARY

In accordance with a first aspect of the present disclosure, there is provided a metal material comprising a plurality of metal particles arranged in a crystal structure having at least two phases; wherein the at least two phases include a crystalline phase and an amorphous phase.

In an embodiment of the first aspect, the crystalline phase includes a nano-crystalline phase and the amorphous phase includes a nano-amorphous phase.

In an embodiment of the first aspect, the plurality of metal particles are arranged to form a plurality of spherical crystalline structures.

In an embodiment of the first aspect, the plurality of metal particles are further arranged to form a plurality of amorphous shells.

In an embodiment of the first aspect, at least a portion of the plurality of spherical crystalline structures is surrounded by the amorphous shell.

In an embodiment of the first aspect, the plurality of spherical crystalline structures are substantially free of dislocation.

In an embodiment of the first aspect, each of the plurality of amorphous shells has a size smaller than or equal to 2 nm.

In an embodiment of the first aspect, the plurality of spherical crystalline structures have a size smaller than or equal to 3 nm.

In an embodiment of the first aspect, a volume ratio between the portion of the metal particles arranged in the crystalline phase and the portion of the metal particles arranged in the amorphous phase substantially ranges from 1:2 to 2:1. Preferably, the ratio is substantially equal to 1:1.

In an embodiment of the first aspect, the at least two phases are distributed uniformly in three dimensional directions in the crystal structure.

In an embodiment of the first aspect, the metal material has an exceptional catalytic performance similar to that of single atom and better than that of nanoclusters with less precious-metal loading, i.e., an overpotential of 21.1 mV at a current density of 10 mA cm⁻², and a Tafel slope of 23.7 mV dec⁻¹ in alkalinity.

In an embodiment of the first aspect, the crystal structure includes a metallic glass structure.

In an embodiment of the first aspect, the plurality of metal particles include aluminum.

In an embodiment of the first aspect, the plurality of metal particles further include at least one of manganese and ruthenium.

In an embodiment of the first aspect, the crystalline phase is equal in composition and the amorphous phase is aluminum-rich.

In an embodiment of the first aspect, an atomic ratio of aluminum, manganese and ruthenium is equal to (100−x−y):x:y where x=7-9 and y=10-30 in the metal material.

In an embodiment of the first aspect, the atomic ratio of aluminum, manganese and ruthenium is equal to 73:7:20 in the metal material.

In accordance with a second aspect of the present disclosure, there is provided a method for producing a metal material, comprising a step of depositing a metal layer comprising a plurality of metal particles on a substrate; wherein the plurality of metal particles are arranged in a crystal structure having at least two phases; and wherein the at least two phases include a crystalline phase and an amorphous phase.

In an embodiment of the second aspect, the metal layer is deposited by a magnetron co-sputtering process.

In an embodiment of the second aspect, an aluminum alloy target and a pure ruthenium target are used during the magnetron co-sputtering process.

In an embodiment of the second aspect, the aluminum alloy target further comprises manganese.

In an embodiment of the second aspect, an atomic ratio of aluminum, manganese and ruthenium is equal to (100−x−y):x:y where x=7-9 and y=10-30 in the metal material.

In an embodiment of the second aspect, the atomic ratio of aluminum, manganese and ruthenium is equal to 73:7:20 in the metal material.

In an embodiment of the second aspect, the aluminum alloy target is fabricated by smelting.

In an embodiment of the second aspect, the magnetron co-sputtering process includes the following parameters:
Vacuum pressure: ≤1×10⁻⁴ Pa;
Argon pressure: 0.2-0.5 Pa;
Substrate bias: 0-−200 V; and
Substrate temperature: 100-200° C.

In an embodiment of the second aspect, the substrate includes at least one of a silicon substrate, a glass substrate and a metal substrate.

In an embodiment of the second aspect, the step of depositing the metal layer comprises adjusting the temperature of the substrate during the deposition process.

### BRIEF DESCRIPTION OF DRAWINGS

Embodiments of the present disclosure will now be described, by way of example, with reference to the accompanying drawings in which:

FIG. 1a shows the structure of the medium-entropy crystal-glass nano-dual-phase Al-based metal material: typical high-angle annular dark-field (HAADF) image probed from a cross-sectional sample. The z-contrast directly reflects the atomic weight difference, i.e. the Al-enriched amorphous regions are darker. The inset shows a typical selected area electron diffraction (SAED) pattern with a halo ring feature, due to extremely small sized nanocrystals and amorphous phase.

FIG. 1b shows the BF-STEM image probed from the same region. The FFT image (upper right inset) of the crystalline region (dashed square on the left) reveals an HCP pattern from the <2 −1 −1 0> zone axis. By contrast, the FFT image (lower right inset) of the dashed square region on the right shows a diffuse pattern, indicating the amorphous structure.

FIG. 2 shows the 1D compositional profile, generated from near-atomic-resolution energy-dispersive X-ray spectrometry mapping.

FIG. 3 shows the stability of the crystal-glass nano-dual-phase Al₇₃Mn₇Ru₂₀ during HER, tested in 1 M KOH solution at 10 mA/cm 2. The inset is the LSV curves before and after the stability test (scanning at 2 mV s⁻¹).

FIG. 4 shows the overpotentials (solid column) and Tafel slopes (striped column) for as-received samples and commercial Pt/C catalyst (loaded with 20 wt. % Pt) tested at 1 M KOH at a scan rate of 2 mV s⁻¹ (with iR loss correction).

FIG. 5 shows the HER catalytic performance comparison with some previously reported noble metal-based catalysts.

FIG. 6 shows the X-ray photoelectron spectroscopy (XPS) of metal materials.

FIG. 7 shows the electrocatalytic performance of annealed sample in 1M KOH solution: linear sweep voltammetry and Tafel slopes with scanning rate of 2 mV s⁻¹ with same iR correction method described in electrochemical measurement.

FIG. 8a shows the cycling voltammetry of commercial 20 wt. % Pt/C in different solutions with scanning rate 10 mV s⁻¹.

FIG. 8b shows the cycling voltammetry of Al₇₃Mn₇Ru₂₀ in different solutions with scanning rate 10 mV s⁻¹.

FIG. 8c shows TOF curve calculated based on current density.

FIG. 9 shows the DFT calculated adsorption energy of H₂O molecules adsorbed on Pt-(111) and different sites on AlMnRu(001) and AlMnRu(100).

FIG. 10 shows the calibration of saturated calomel electrode in 1 M KOH with H₂ atmosphere.

### DETAILED DESCRIPTION

The present disclosure will be further described in detail below with reference to the drawings and in conjunction with the embodiments. It can be understood that the specific embodiments described here are only used to explain the related invention, rather than limiting the invention.

Renewable clean energy technology is developing rapidly in the past few decades, and abundant clean fuels, such as hydrogen (H₂), are expected to replace fossil fuels in the future. Electrocatalytic water splitting is a reliable, eco-friendly, and widely-used technique to produce hydrogen in the industry. Pt-based catalysts are used in hydrogen evolution reaction (HER) towards water electrolysis, which are regarded as a class of the most efficient catalysts in both acid and alkaline electrolytes, yet the concern of their price is still an issue. Therefore, the demand to develop low-cost and reliable electrocatalysts is desired. Because of excellent performances during the HER process, Ru-based catalysts have received extensive attention in recent years, due to the cost-effective element Ru compared to Pt among precious metals.

One of the key challenges in the design of new catalysts is the synthesis of high-performance materials with controlled structures. In the recent studies, it has been found that good catalytic properties are obtained in amorphous phases, benefitting from a higher density of defective sites and thus a reduced energy barrier for hydrogen evolution, compared to those of their crystalline counterparts. The amorphous phases gain widespread attention by virtue of robust active size resulted from its unique electronic structure. For instance, the amorphous noble-metal Au-based catalyst, prepared using the graphene oxide aqueous solution, shows a higher electrocatalytic activity for N₂ reduction reaction, compared to its crystalline counterpart.

In order to improve the HER performance of the crystalline materials, lots of efforts have been paid towards tuning their lattice structures. In the recent decade, crystalline multicomponent alloys were developed. The alloys reveal local chemical inhomogeneity, short-range ordering, and severe lattice distortion, which optimize catalytic reactivity for HER.

Combining crystalline and amorphous phases together to form a nanocomposite structure is an effective approach for achieving excellent HER performance, due to the unique active sites from the two phases. In addition, multiple studies focused on nanoparticles or clusters have confirmed the advantage of small-size catalysts. Therefore, cooperating the crystal-glass dual-phase structure and the size effect should be a desirable method to fabricate new-generation catalysts.

The inventors fabricate a metal material demonstrating the nano-dual-phase structure, via a new route that can fabricate a large quantity of highly active electrocatalysts by high-throughput combinatorial magnetron co-sputtering. By virtue of the effect of the nano-dual-phase structure, excellent catalytic performances (21.1 mV for the overpotential at 10 mA cm⁻¹, and 23.7 mV dec⁻¹ for the Tafel slope) were obtained for the Al-based metal material, in addition to excellent mechanical properties such as high strength and high toughness.

As the size limit of the medium-range order in amorphous phase is from 1 to 2 nm, the minimum size of the structural unit here has been reached to 2 nm. The sized magnitude of the structural unit in this system increases the catalytic performance to the extreme due to the greatly improvement of the reaction energy barrier, and the synergistic effect activated by the dual-phase.

As discovered by the inventors, the metal material has an important implication in improving the catalytic property of metallic materials. The strategy proposed herein provides guidance for efforts to design the new system and understand the structure-property relationship for electrocatalysts, which is also applicable in other multi-component systems.

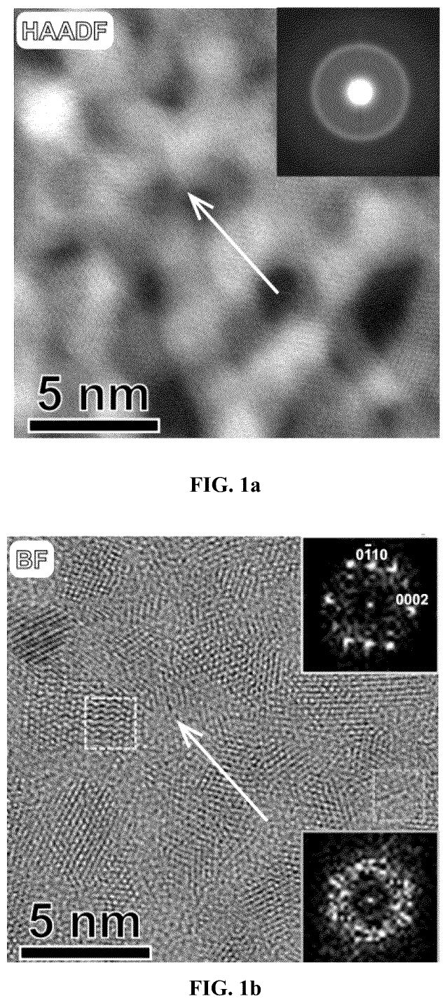

With reference to FIG. 1a, there is provided a metal material comprising a plurality of metal particles arranged in a crystal structure having at least two phases; wherein the at least two phases include a crystalline phase and an amorphous phase. For example, the Al-based metal material introduced herein was obtained by doping Ru into an Al—Mn system. In this embodiment, the metal material preferably comprises a plurality of metal particles selected from a combination of aluminum, manganese, and ruthenium. These metal particles may be arranged in a crystal structure, for example, a metallic glass structure, with at least a crystalline phase and an amorphous phase. For instance, the grains with a lattice structure are the crystalline phases, and the material between the grains is the amorphous phase, as shown in FIG. 1a. In particular, when the atomic ratio of aluminum, manganese and ruthenium is equal to (100−x−y):x:y where x=7-9 and y=10-30 in the metal material, the metal material has an exceptional catalytic performance similar to that of single atom and better than that of nanoclusters with less precious-metal loading, in addition to excellent mechanical properties such as strength and toughness.

These AlMnRu catalysts were synthesized by magnetron co-sputtering of Al₈₀Mn₂₀ (at. %) alloy and Ru targets with 99.9 at. % purity. The composition of the Al-based catalyst investigated in the following experiment is Al₇₃Mn₇Ru₂₀ (at. %), revealed by energy dispersion spectrum (EDS). The catalyst has a crystal-glass nano-dual-phase structure which reveals ˜2 nm-diameter amorphous regions embedded between −2 nm-diameter globular nanograins (FIG. 1a and FIG. 1b).

Each of the spherical crystalline structures and the amorphous shells may have a size smaller than or equal to 3 nm. For instance, the volume ratio of the spherical crystalline structures to the amorphous shells within the metal material may be from 1:2 to 2:1, and more preferably around 1:1, to distribute the spherical crystalline structures and the amorphous shells uniformly in a three dimensional directions.

Preferably, the selected area electron diffraction pattern (SAED) shows an amorphous ring and several crystalline rings corresponding to the hcp AlMnRu phase equiaxed with random orientations. Furthermore, the statistical analysis shows the uniform distribution of the nanocrystals with the average diameter of 2 nm.

Preferably, the structure in one exemplary embodiment of the present disclosure possesses a catalytic performance of an overpotential of 21.1 mV at a current density of 10 mA cm⁻¹, and a Tafel slope of 23.7 mV dec⁻¹ in alkalinity during HER. A 2-μm-thick homogeneous film with large area of 10 cm×10 cm can be deposited in just one sputtering process, which widens its industrial application to fabricate new-generation catalysts.

The amorphous phase in the material in one exemplary embodiment of the present disclosure has the virtue of robust active size resulted from its unique electronic structure. Accordingly, the catalytic performance for hydrogen evolution may be further increased as the grain size further decreases below 3 nm. Preferably, the volume ratio of the crystalline phases to the amorphous phase is ideally 2:1-1:2, because there is a compensation effect between grain boundary sliding for the crystalline phase and shear transition effect for the amorphous phase.

The nanograins with a diameter of around 2-3 nm are dispersed uniformly in the amorphous matrix, revealing an amorphous-nanocrystalline dual-phase structure. The inventors have devised that an active catalyst is provided with a nanocrystalline dual-phase structure. The first crystalline phase may be spherical crystalline that are substantially free of dislocation and preferably, the grain size may be around 2 nm. On the other hand, the second phase may be an amorphous phase for surrounding the spherical crystalline phase and preferably, the grain size may be around 1 nm.

Preferably, the metal material produced by magnetron co-sputtering has a homogeneous structure in 3D, which is very different from the granular/columnar structure of the traditional sputtered thin films. Such metal material with the amorphous-nanocrystalline dual-phase structure could be called as nano-dual-phase glass-crystal.

Turning now to the method for producing the metal material, the method includes a step of depositing a metal layer comprising a plurality of metal particles on a substrate, preferably with an alloy target being used in a magnetron co-sputtering process. The plurality of metal particles is arranged in a crystal structure having at least two phases including a crystalline phase and an amorphous phase. Alternatively, any surface coating technology, such as but not limited to sputtering and evaporation, which allows an adjustment of the material cooling rate, may be applied to form the aforesaid two phases coating. These processes are simple yet low cost, and thus widen the application of the alloy coating product and also overcome the tough fabrication requirement of nanocrystalline materials.

Preferably, the alloy targets may be an aluminum alloy target comprising manganese and a pure ruthenium target, which are fabricated by smelting. More preferably, the alloy target may be arranged with an atomic ratio of aluminum, and manganese of 85:15. Alternatively, co-sputtering of multiple targets of metal materials may be adopted.

In one embodiment, the method for producing the nano-dual-phase glass-crystal metal material comprises the steps of:

Step 1: Washing a substrate to be deposited. The substrate is first placed into acetone for ultrasonic cleaning of 10 minutes. The substrate is then placed into alcohol for ultrasonic cleaning of 10 minutes. Subsequently, the alcohol on the surface is dried with a nitrogen gun.

Step 2: Fabricating one aluminum-manganese alloy target and one pure ruthenium target for use in the sputtering process. Preferably, the raw material of the targets has a purity of higher than 99.9%. Preferably, the method for fabricating the targets may be smelting, molten melting, or powder pressing.

Step 3: Placing the targets and the washed substrate into a sputtering cavity. Suitable parameters may be selected according to the heat index of the material for performing magnetron co-sputtering, thereby obtaining the metal material with excellent performances. Preferably, the sputtering vacuum pressure is ≤1×10⁻⁴ Pa, more preferably lower than 5.5×10⁻⁵ Pa, the substrate heating temperature is around 100 to 200° C., the deposition rate is 5 to 8 nm/min, and the substrate bias voltage is around 0 to −200 V.

In yet another embodiment, the method for producing the nano-dual-phase glass-crystal metal material comprises the steps of:

Step 1: Placing the targets and substrate into a sputtering cavity. The sputtering parameters are adjusted to suitable parameters for performing magnetron sputtering, thereby obtaining the material with the alloy coating. Preferably, the sputtering vacuum pressure is ≤1×10⁻⁴ Pa, more preferably lower than 5.5×10⁻⁵ Pa, the Argon pressure is between 0.2 to 0.5 Pa, the substrate heating temperature is around 100 to 200° C., the deposition rate is 5 to 8 nm/min, and the substrate bias voltage is around 0 to −200 V.

Step 2: Fabricating an alloy target with an atomic ratio of aluminum, and manganese equal to 85:15, and a pure ruthenium target. Preferably, the raw materials of the alloy target and the pure ruthenium target have a purity of higher than 99.9%. Preferably, the method for fabricating the alloy target and the pure target may be smelting, molten melting, or powder pressing.

Step 3: Using monocrystalline sheet with a clean surface, regular glass sheet, or alloy substrate as the substrate.

Preferably, the target for sputtering may be a glass-forming target, and the elements of the target are not limited to only aluminum, manganese, and ruthenium. The substrate may be washed with the following steps: the substrate is first placed into acetone for 60 W ultrasonic cleaning of 10 minutes; the substrate is then placed into alcohol for 60 W ultrasonic cleaning of 10 minutes; subsequently, the alcohol on the surface is dried with a nitrogen gun.

Optionally, the production method may also be co-sputtering with two or more targets. Any surface coating technology, such as but not limited to sputtering and evaporation, which allows an adjustment of the material cooling rate, may be applied to form the aforesaid two phases coating.

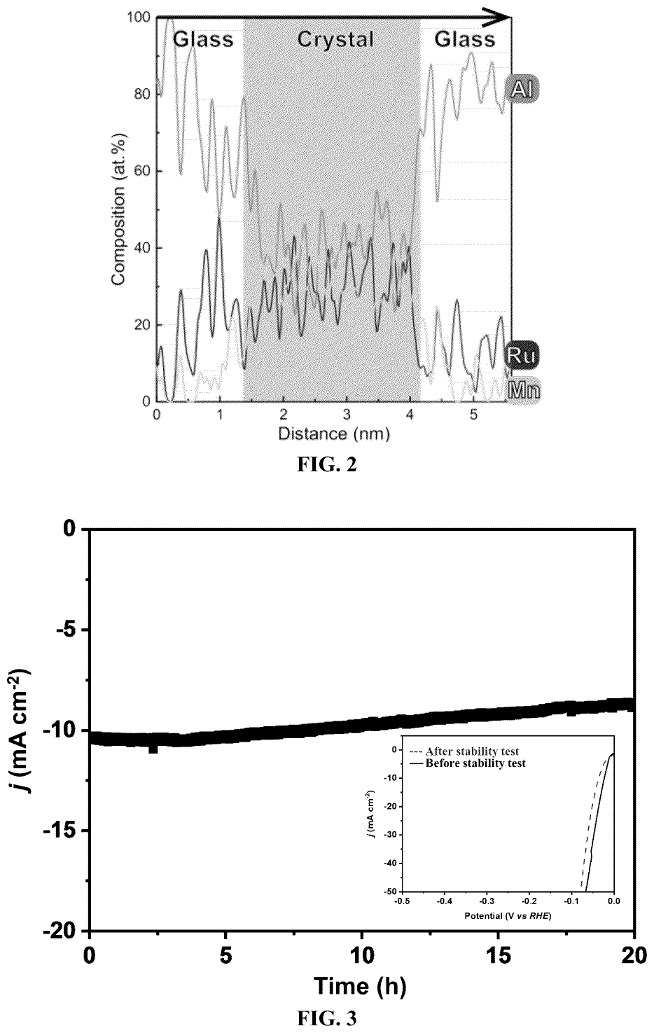

With reference to FIG. 2, the composition of the nanograins is AlMnRu in a near-equiatomic ratio, shown by the 1D compositional profile. The nanograins reveal typical HCP planes shown in bright-field high-resolution (BF-HR) STEM image (FIG. 1b), without crystallographic planes of other crystalline phases. The solid solution HCP structure of the nanograins benefits from the medium-entropy configuration of the composition with a near-equiatomic ratio.

As it would be appreciated by person skilled in the art, Al₇₃Mn₇Ru₂₀ is not a very good glass forming composition. The HCP phase is formed because of the appropriate heating in the sputtering process, leaving behind the relaxed Al-enriched amorphous shell with good glass forming ability (GFA). The Al-based nano-dual-phase glass-crystal with one quasi “dislocation free” crystalline phase uniformly dispersed in the relaxed amorphous shell is achieved in just one deposition process, which reveals a self-assemble property of this nano-dual-phase glass-crystal structure.

With reference to FIG. 3, the HER stability of the crystal-glass nano-dual-phase Al₇₃Mn₇Ru₂₀ tested in 1M KOH solution at 10 mA/cm² is shown. The inset is linear sweep voltammetry curves before and after stability test, scanning at 2 mV s⁻¹. the current-time curve carried out at 10 mA cm⁻² is relatively steady, confirming the high stability of the as-received Al₇₃Mn₇Ru₂₀ electrocatalyst. The weak reduction might be related to minor dissolution of Al into the alkaline solution, due to the amphoteric property of Al.

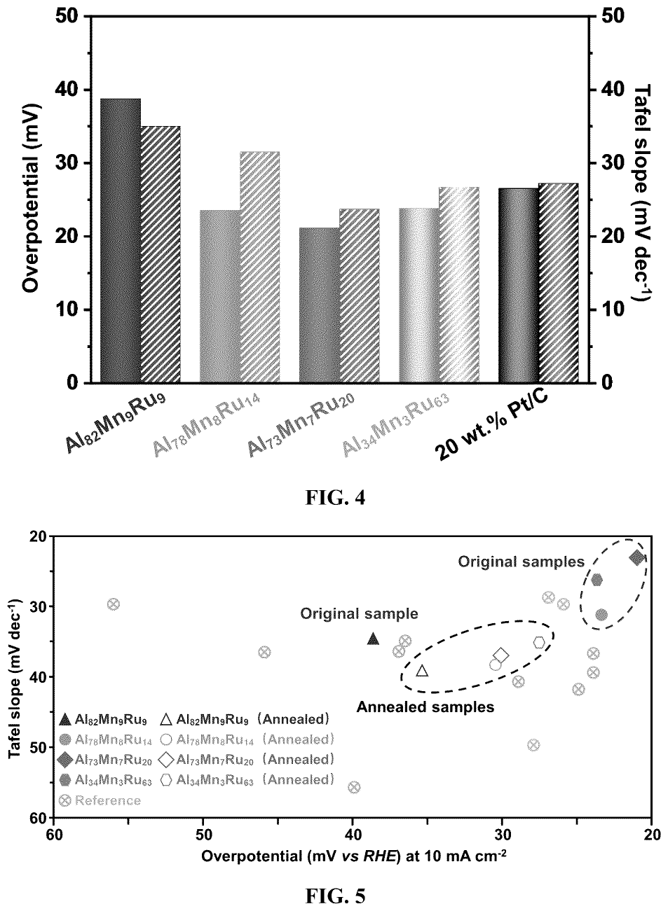

With reference to FIG. 4, the value of overpotentials (solid column) and Tafel slopes (Striped column) for the as-received samples and commercial Pt/C catalyst (loaded with 20 wt. % Pt) tested at 1M KOH at a scan rate of 2 mV s⁻¹ with iR loss correction is shown. Nano-dual-phase structure supported on carbon cloth presents excellent catalytic capacity for HER with a lower overpotential and faster kinetics, which are evaluated and compared with commercial Pt/C catalyst (20 wt. % Pt) in alkaline solution. As shown in FIG. 4, the linear sweep voltammetry (LSV) curves suggest that both amorphous, dual-phase nanostructure, and crystalline structure have advanced ability for activating the reaction of hydrogen evolution although they are oxidized.

With reference to FIG. 5, the HER performance comparison among noble metal based catalysts and the samples in the current study is shown. To our best knowledge, the crystal-glass nano-dual-phase Al₇₃Mn₇Ru₂₀ (at. %) reveals the best HER performance compared to that of noble metal based HER catalysts.

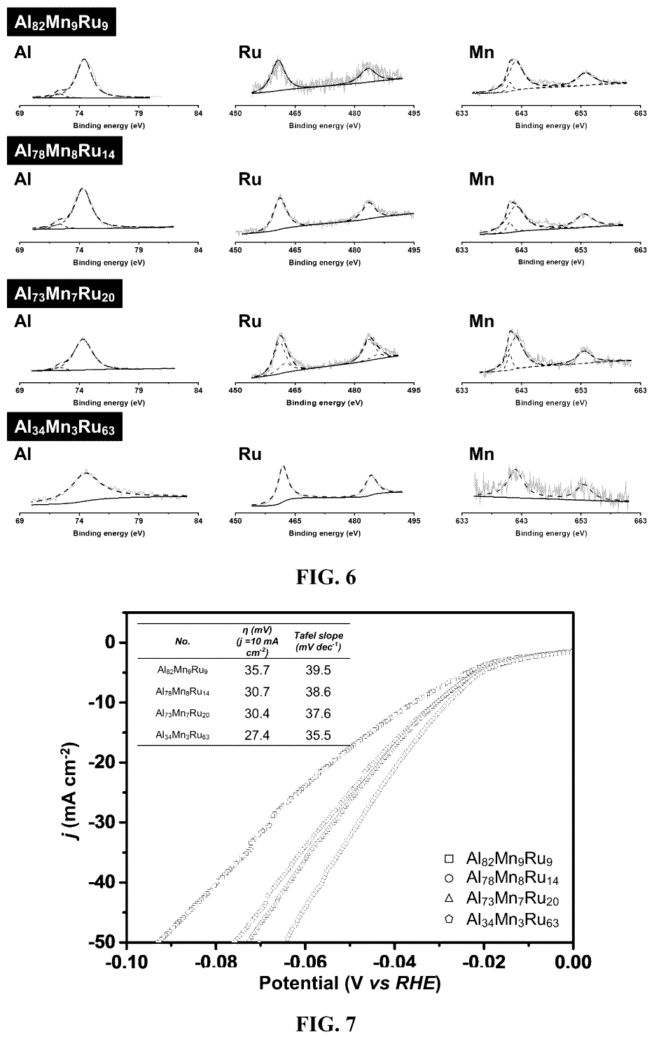

With reference to FIG. 6, the X-ray photoelectron spectroscopy (XPS) of metal materials is shown. The crystalline structure have advanced ability for activating the reaction of hydrogen evolution although they are oxidized.

With reference to FIG. 7, the electrocatalytic performance of annealed sample in 1M KOH solution is shown, including linear sweep voltammetry and Tafel slopes with scanning rate of 2 mV s⁻¹ with same iR correction method described in electrochemical measurement. The electrocatalytic performance of all annealed samples, especially the amorphous (including Al₇₈Mn₈Ru₁₄ and Al₈₂Mn₉Ru₉) and dual-phase ones (Al₇₃Mn₇Ru₂₀) (at. %), become worse. This reduction strongly confirms that the superior HER performance of Al₇₃Mn₇Ru₂₀ (at. %) is attributed to its nano-dual-phase structure. Moreover, the relatively poorer HER performance of Al₃₄Mn₃Ru₆₃ (at. %) with highly crystalline structure signifies that higher Ru concentration weakens the catalytic capacity, which in turn confirms the advance of the crystal-glass nano-dual-phase structure with lower Ru concentration. Therefore, this specific transformation tendency in both original and annealed system of HER ability illustrates the crystal-glass nano-dual-phase structure have extra superior capacity for water splitting, which is also confirmed by electrochemical impedance spectroscopy.

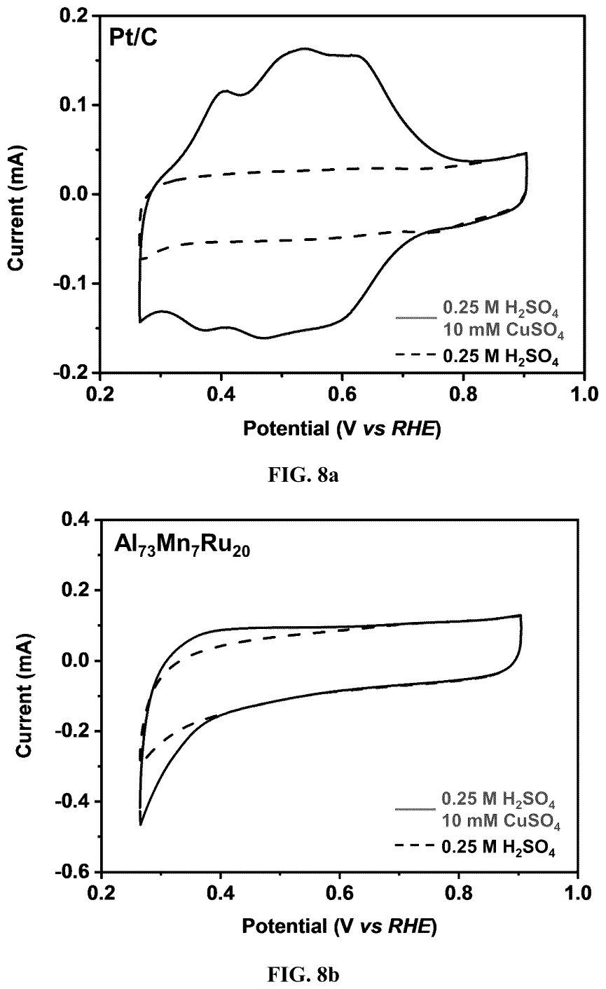

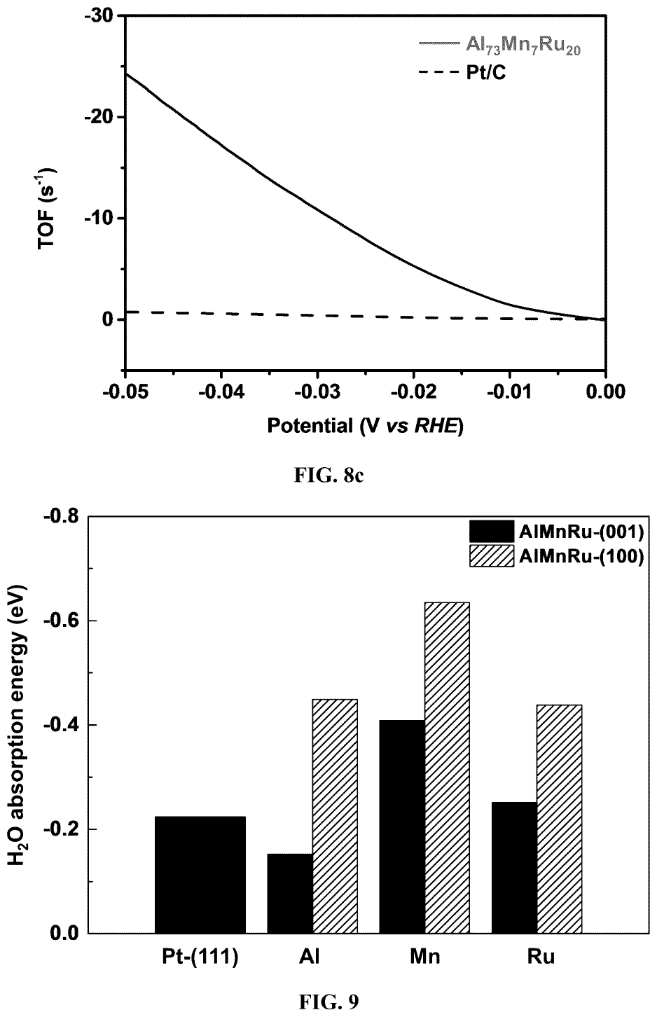

With reference to FIG. 8a, the cycling voltammetry of commercial 20 wt. % Pt/C in different solutions with scanning rate 10 mV s⁻¹ is shown. In order to reveal the catalytic ability of single active site, the TOF value of dual-phase and Pt/C was calculated. Based on the amount of underpotential deposition of Cu²⁺, the TOF value of Al₇₃Mn₇Ru₂₀ is about 0.71|j|, while this value of commercial Pt/C catalyst is only about 0.05|j|. After substituting the current density into the above TOF calculation, Al₇₃Mn₇Ru₂₀ exhibit an extra high TOF of 24.3 s⁻¹ at 50 mV than that of Pt/C (0.90 s⁻¹). To our best knowledge, the crystal-glass nano-dual-phase Al₇₃Mn₇Ru₂₀ (at. %) reveals the best HER performance compared to that of noble metal based HER catalysts. We note that the current-time curve carried out at 10 mA cm⁻² is relatively steady, confirming the high stability of the as-received Al₇₃Mn₇Ru₂₀ electrocatalyst. The weak reduction might be related to minor dissolution of Al into the alkaline solution, due to the amphoteric property of Al.

With reference to FIG. 8b, cycling voltammetry of Al₇₃Mn₇Ru₂₀ in different solutions with scanning rate 10 mV s⁻¹ is shown.

With reference to FIG. 8c, TOF curve calculated based on current density is shown.

With reference to FIG. 9, the DFT calculated adsorption energy of H₂O molecules adsorbed on Pt-(111) and different sites on AlMnRu(001) and AlMnRu(100) is shown. Theoretical calculations were conducted to unveil the HER mechanism of the AlMnRu system using density functional theory (DFT). Two exposed surfaces of AlMnRu, i.e. (001) and (100) facets, were selected to study the well-accepted Volmer-Heyrovsky reaction, while the situation on Pt (111) was demonstrated for comparison. As for the Volmer step of H₂O adsorption and dissociation, the adsorption energy (E_{water}) of H₂O molecule adsorbed on the top of a single metal atom (Al, Mn, and Ru) on each exposed surface is shown. All the adsorption sites, except for the Al sites on AlMnRu (001) facet, exhibit a preferable E_{water} than that of Pt (111), indicating the water adsorption process is favoured on these exposed surfaces, which significantly enhances the efficiency of the catalytic process.

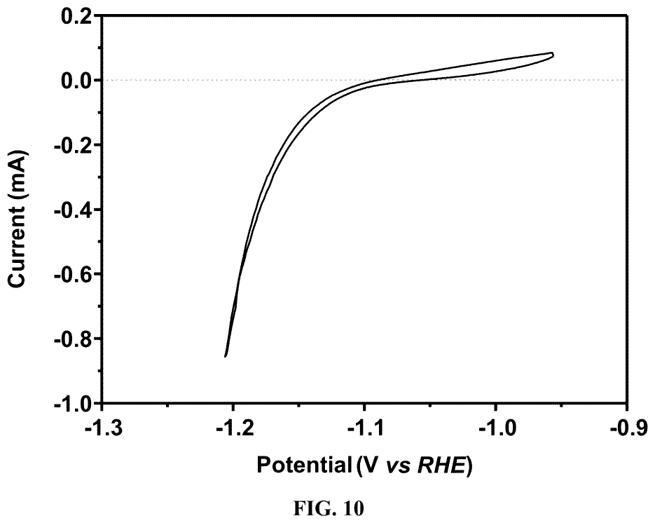

With reference to FIG. 10, the calibration of saturated calomel electrode in 1 M KOH with H₂ atmosphere is shown. The saturated calomel electrode was calibrated in H₂ saturated 1M KOH solution with scanning rate of 2 mV s⁻¹ to further guarantee the accuracy of potentials.

The above descriptions are just the preferred embodiments of the present disclosure and explanations of the applied technical principles. Those skilled in the art should understand that the scope of the invention involved in the present disclosure is not limited to the technical solutions formed by specific combinations of the above technical features, and should also cover other technical solutions formed by arbitrary combinations of the above technical features and their equivalents without departing from the concept of present disclosure, such as the technical solutions formed by mutually replacing the above technical features and those with similar functions disclosed in the present disclosure (but not limited thereto).

What is claimed is:

1. A metal material comprising a plurality of metal particles arranged in a crystal structure having at least two phases; wherein the at least two phases include a crystalline phase and an amorphous phase.

2. The metal material in accordance with claim 1, wherein the crystalline phase includes a nano-crystalline phase and the amorphous phase includes a nano-amorphous phase.

3. The metal material in accordance with claim 1, wherein the plurality of metal particles are arranged to form a plurality of spherical crystalline structures and a plurality of amorphous shells.

4. The metal material in accordance with claim 3, wherein at least a portion of the plurality of spherical crystalline structures is surrounded by the amorphous shell.

5. The metal material in accordance with claim 3, wherein each of the plurality of amorphous shells has a size smaller than or equal to 2 nm.

6. The metal material in accordance with claim 3, wherein the plurality of spherical crystalline structures have a size smaller than or equal to 3 nm.

7. The metal material in accordance with claim 1, wherein a volume ratio between the portion of the metal particles arranged in the crystalline phase and the portion of the metal particles arranged in the amorphous phase substantially ranges from 1:2 to 2:1, or substantially equal to 1:1.

8. The metal material in accordance with claim 1, wherein the at least two phases are distributed uniformly in three dimensional directions in the crystal structure.

9. The metal material in accordance with claim 1, wherein the crystal structure includes a metallic glass structure.

10. The metal material in accordance with claim 1, wherein the plurality of metal particles include aluminum.

11. The metal material in accordance with claim 10, wherein the plurality of metal particles further include at least one of manganese and ruthenium.

12. The metal material in accordance with claim 11, wherein the crystalline phase is equal in composition and the amorphous phase is aluminum-rich.

13. The metal material in accordance with claim 11, wherein an atomic ratio of aluminum, manganese and ruthenium is equal to (100−x−y):x:y where x=7-9 and y=10-30, preferably 73:7:20 in the metal material.

14. A method for producing a metal material, comprising a step of depositing a metal layer comprising a plurality of metal particles on a substrate; wherein the plurality of metal particles are arranged in a crystal structure having at least two phases; and wherein the at least two phases include a crystalline phase and an amorphous phase.

15. The method in accordance with claim 14, wherein the metal layer is deposited by a magnetron co-sputtering process.

16. The method in accordance with claim 15, wherein an aluminum alloy target and a pure ruthenium target are used in the magnetron co-sputtering process.

17. The method in accordance with claim 16, wherein the aluminum alloy target further comprises manganese.

18. The method in accordance with claim 17, wherein an atomic ratio of aluminum, manganese and ruthenium is equal to (100−x−y):x:y where x=7-9 and y=10-30, preferably 73:7:20 in the metal material.

19. The method in accordance with claim 15, wherein the magnetron co-sputtering process includes the following parameters:
Vacuum pressure: ≤1×10⁻⁴ Pa;
Argon pressure: 0.2-0.5 Pa;
Substrate bias: 0-−200 V; and
Substrate temperature: 100-200° C.

20. The method in accordance with claim 14, wherein the step of depositing the metal layer comprises adjusting the temperature of the substrate during the deposition process.
